(19) United States
(12) Patent Application Publication
(10) Pub. No.: US 2003/0183948 A1
(43) Pub. Date: Oct. 2, 2003

(54) Golden unit

(76) Inventors: Yew Fei Tham, Singapore (SG); Vijay Kumar Dharmadhikari, Singapore (SG)

Correspondence Address: AGILENT TECHNOLOGIES, INC., Legal Department, DL429, Intellectual Property Administration, P.O. Box 7599, Loveland, CO, 80537-0599, US

(21) Appl. No.: 10/402,555

(22) Filed: Mar. 27, 2003

(30) Foreign Application Priority Data
Apr. 1, 2002 (SG) 200201681-4

(51) Int. Cl. H01L 23/48; H01L 23/52; H01L 29/40

(52) U.S. Cl. 257/780

(57) ABSTRACT

A ball grid array unit suitable for calibrating an inspection system, comprising a substrate and an array of balls mounted on a surface of the substrate, the balls having a melting point greater than 400 degrees centigrade or a Britnell hardness number greater than 150.

The present invention relates to a ball grid array unit suitable for calibrating inspection systems, and a method of manufacturing such a unit.

Semiconductor integrated circuit (IC) chips are typically supplied in a variety of package designs, including quad flat packages, pin grid packages, and ball grid array packages. A known semiconductor ball grid array (BGA) package is disclosed in U.S. Pat. No. 5,409,865. As described in the patent, a BGA package is generally a surface-mount package that is assembled to an external or “mother” printed circuit board (PCB) using an area array of solder balls, instead of fine pitch in-line leads which are easily damaged during the process of installing the IC on an external PCB. The BGA package uses solder balls to electrically connect the integrated circuit (IC) to metallic traces on an external PCB. The solder balls of the BGA package are typically formed from eutectic solder which is designed to melt at temperatures ranging between 150-300° C. during the process of attachment of the BGA package to the external PCB.

The process of manufacturing semiconductor ball grid array (BGA) packages typically includes a quality control step whereby the packages are inspected using an inspection system. Known inspection systems include 2-D vision inspection systems based on front lighting and back-lighting, 3-D vision inspection systems based on structured light, and 3-D laser-based inspection systems. The features of the BGA package that are inspected by the inspection systems include:

Package Width and Length

Ball pitch

Ball diameter

Individual Ball offset

Ball matrix offset

Ball height

Ball coplanarity

Substrate warpage

To inspect manufactured BGA packages for defects in the above characteristics, the inspection systems requires calibration to a known standard BGA unit, also known as a golden unit. The following are preferred characteristics of a golden unit:

1) Surface finish which remains consistent over time, i.e., the unit does not tarnish easily.

2) Dimensions which remain consistent over time, i.e., the unit is not prone to physical damage due to temperature cycling, humidity, or manual handling.

3) Accurate ball shape—ideally a perfect sphere.

4) Quality ball finish, i.e., no defects on ball surface.

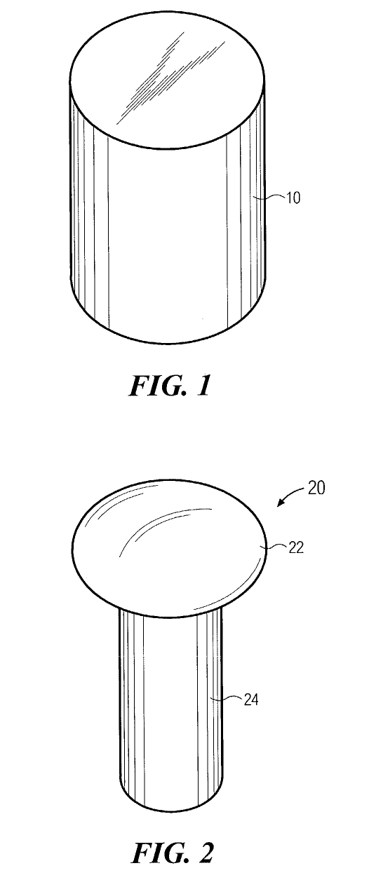

Traditionally, golden BGA units are fabricated from steel parts by mechanical machining. As illustrated in FIGS. 1 and 2, the fabrication process involves accurately machining a steel rod 10 down to a mushroom-shaped pin 20, with a spherical head 22 and a narrower cylindrical shaft 24. The spherical head represents the solder ball of the ball grid array package.

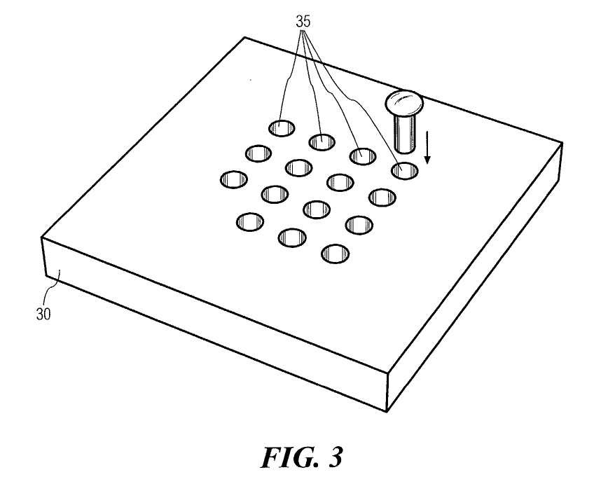

Referring to FIG. 3, the fabrication process further comprises accurately drilling a steel substrate 30 with an array of cylindrical holes 35 of slightly larger diameter than the cylindrical shaft 24 of the mushroom-shaped pin 20. The mushroom-shaped pin 20 is then inserted into one of the holes 35 in the array. Further mushroom-shaped pin 20 are fabricated and inserted into the remaining holes 35 of the array. The pins 20 are held in the holes 35 either by an interference fit between the cylindrical shaft and the hole, or by means of an epoxy adhesive.

Once the golden BGA unit is made, the position of the balls and the dimensions of the base are measured with extremely high-accuracy using a slow inspection system. The golden unit is then sold together with the results of the high-accuracy inspection system. The results provide the specifications unique to a particular golden BGA unit, and are often referred to as the birth certificate for the golden BGA unit.

Because the pins 20 of golden BGA unit are made from steel, their surface finish remains consistent over time with little tarnishing. The accurate machining ensures an accurate ball shape and a quality ball finish with minimal defects. Because the base is made of steel, the dimensions of the unit remain consistent over time, and the unit is less prone to physical damage due to temperature cycling, humidity, or manual handling.

However, a major drawback with the traditional approach to manufacturing golden BGA units is the high cost associated with the accurate machining of the mushroom-shaped pins 20, and with the accurate drilling of the substrate 30.

The traditional method of manufacturing a golden BGA unit includes the step of accurately drilling the steel substrate with an array of cylindrical holes. The applicant has found that although accurate ball shape and a quality ball finish are desirable features for a golden BGA unit, the need for accurate positioning of the balls is not a critical feature for a golden BGA unit, since this positioning characteristic can be supplied as part of the specifications of the golden BGA unit in the birth certificate.

The applicant has discovered a need for a golden BGA unit which can be manufactured at low cost but with the preferred characteristics of a traditionally expensive golden unit.

According to a first aspect of the present invention there is provided a ball grid array unit suitable for calibrating an inspection system, comprising a substrate, and an array of balls mounted on a surface of the substrate, the balls having a melting point greater than 400 degrees centigrade.

According to a second aspect of the present invention there is provided a ball grid array unit suitable for calibrating an inspection system, comprising a substrate, and an array of balls mounted on a surface of the substrate, the balls having a Brinell hardness factor greater than 150.

According to a third aspect of the present invention there is provided a method of manufacturing a ball grid array unit suitable for calibrating an inspection system, comprising providing a substrate, and mounting balls having a melting point greater than 400 degrees centigrade to a surface of the substrate.

According to a fourth aspect of the present invention there is provided a method of manufacturing a ball grid array unit suitable for calibrating an inspection system, comprising providing a substrate, and mounting balls having a Brinell hardness number lower than 150 to a surface of the substrate.

Embodiments of the invention will now be described, by way of example, with reference to the accompanying drawings, in which:

FIG. 1 is a perspective view of a steel rod used in the fabrication process according to the prior art;

FIG. 2 is a perspective view of a mushroom-shaped pin machined from the steel rod of FIG. 1;

FIG. 3 is a perspective view of a substrate and pin according to the prior art;

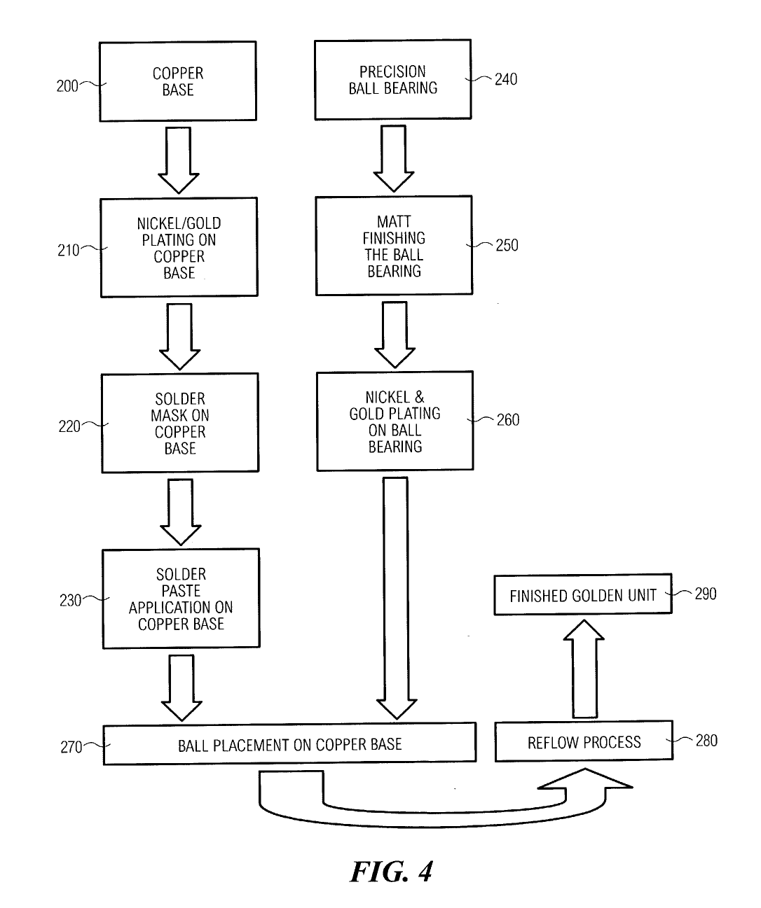

FIG. 4 is a flow chart showing the preferred steps in making a golden unit in accordance with the invention;

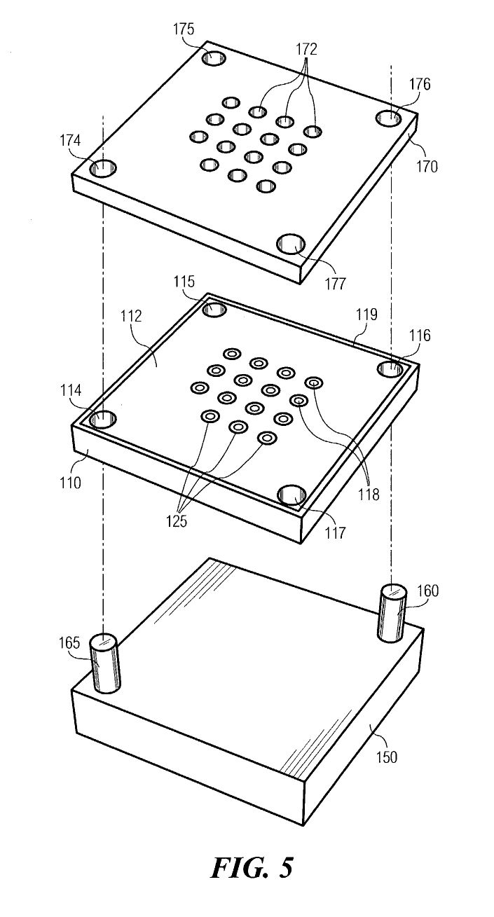

FIG. 5 is a perspective view illustrating the process of applying solder to the copper base in accordance with the invention;

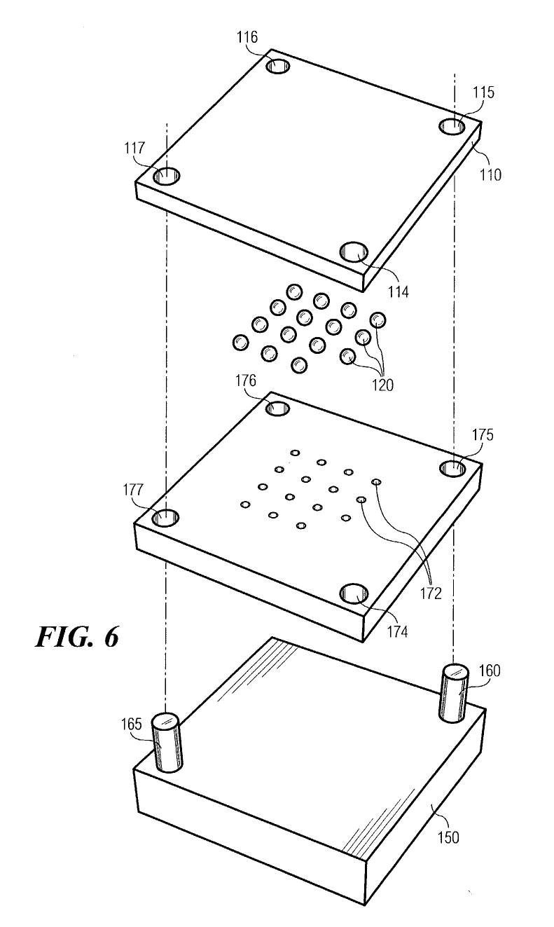

FIG. 6 is a perspective view illustrating the process of placing the balls on the copper base in accordance with the invention; and

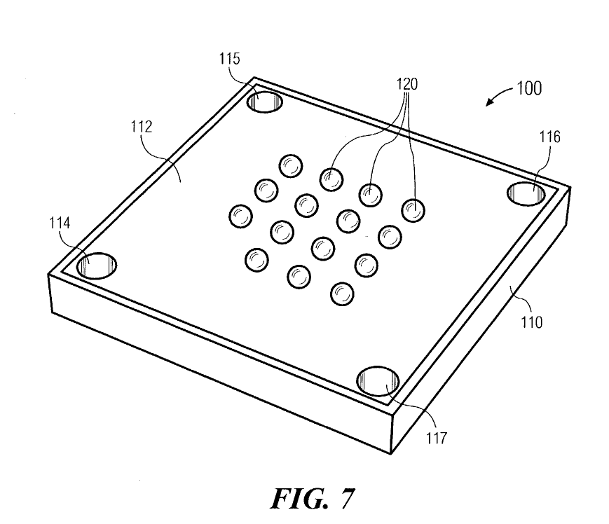

FIG. 7 is a perspective view of a golden BGA unit in accordance with the invention.

Referring to FIG. 7, there is shown a golden BGA unit 100 in accordance with the invention comprising a base or substrate 110, and an array of balls 120 mounted on a top surface 112 of the substrate 110. The 15 balls 120 are arranged in a 4×4 grid with one corner containing no ball to indicate the orientation of the unit when it is inspected by an inspection system. The substrate 110 may have dimensions of 25 mm×25 mm×2 mm, and includes four through holes 114, 115, 116, 117 between the major surfaces near the four corners of each major surface. The balls are substantially spherically shaped and may have a diameter of 1.4 mm. The ball-to-ball pitch may be 2 mm. The substrate.

The substrate 110 and the balls 120 may be both made of metal, such as copper or steel coated with nickel and gold. The substrate and balls may also be made of other material, such as ceramic. To provide the following characteristics in the golden unit 100, the balls 120 may be made of a material which has a Brinell hardness number greater than 150:

1) Surface finish which remains consistent over time, i.e., the unit does not tarnish easily.

2) Accurate ball shape—ideally a perfect sphere.

3) Quality ball finish, i.e., no defects on ball surface.

FIG. 4 shows the steps in manufacturing the golden BGA unit of FIG. 7 in accordance with the invention. In step 200, a copper base is provided having dimensions 25 mm×25 mm×2 mm. The copper base is drilled at positions on a major surface corresponding to the bottom of the balls in FIG. 7 to form depressions or dimples 118 in the surface 112, as shown in FIG. 5. The depressions have a circular top edge of diameter 0.25 mm, and have a depth of 0.25 mm. Four through holes 114, 115, 116, 117 are also drilled between the major surfaces of the copper base near the four corners of each major surface, as shown in FIGS. 5 and 7.

In step 210, the whole of the copper base is plated with 5 μm of nickel and then 5 μm of gold using standard plating techniques.

In step 220, a solder mask 119 is deposited on the gold plated surface of the copper base using standard silk screen printing techniques as used in PCB manufacture. The solder mask defines an array of circular apertures 125 of diameter 0.6 mm around the array of dimples 118, as shown in FIG. 5.

In step 230, the copper base is mounted on metal jig 150 with alignment pins 160 and 165 sliding into the through holes 116 and 114 respectively. A stainless steel stencil 170 of thickness 200 μm is then placed over the surface of the copper base 110 containing the dimples 118 and the solder mask 119. The stencil 170 has the through-holes 174, 175, 176, 177 which correspond to the through-holes 114, 115, 116, 117 of the copper base. The alignment pins 160 and 165 slide into the through holes 176 and 174 respectively. With the stencil in position, a second set of through holes 172 of the stencil correspond with the size and position of the solder mask apertures 125. Solder paste is then silk screened over the through-holes 172 to deposit 15 cylindrical pads of solder paste of thickness 200 μm and diameter 0.6 mm over the dimples 118.

Meanwhile, precision ball bearings made of stainless steel are provided in step 240. These are available at very low cost in a variety of sizes and materials. In step 250, the ball bearings or balls are matte finished so that they can be plated easily with 5 μm of nickel and then 5 μm of gold using standard plating techniques in step 260.

Step 270 is illustrated in FIG. 6. The copper base 110 and the stencil 170 have both been flipped over. The stencil is then placed over the same jig 150 but with the pins 160 and 165 sliding into holes 175 and 177 respectively. The gold plated balls 120 are then aligned and rested on the aperture 172. The copper base 110 is then lowered over the stencil containing the balls 120. The pins 160 and 165 now slide into holes 115 and 117. As the copper base 110 is lowered under its own weight onto the balls 120, the balls align with and stick to the 15 cylindrical pads of solder paste. The whole jig is then carefully turned over and the jig and the stencil are lifted off the copper base now supporting the balls 120.

The copper base 110 supporting the balls 120 is then reflow soldered at a temperature of between 100 and 300° centigrade to melt the solder paste, and self-align the balls 120. When the solder cools in step 290, it adheres the balls 120 to the copper base 110 to form a finished golden BGA unit as shown in FIG. 7. The finished unit has been tested to be accurate and durable. The ball bearings coated with gold provide an excellent finish for 3-D vision inspection, are spherically shaped, and have minimal defects.

1. A ball grid array unit for calibrating an inspection system, comprising:
a substrate and an array of balls mounted on a surface of the substrate, the balls having a melting point greater than 400 degrees centigrade.

2. The ball grid array unit as claimed in claim 1, wherein the balls are adhered to the surface of the substrate with solder having a melting point lower than 400 degrees centigrade.

3. The ball grid array unit as claimed in claim 1, wherein the surface of the substrate includes an array of depressions in which the balls sit.

4. The ball grid array unit as claimed in claim 1, wherein the substrate is made of metal and the balls are made of metal.

5. The ball grid array unit as claimed in claim 1, wherein the substrate is gold plated and the balls are gold plated.

6. A ball grid array unit for calibrating an inspection system, comprising:
a substrate and an array of balls mounted on a surface of the substrate, the balls having a Brinell hardness number greater than 150.

7. The ball grid array unit as claimed in claim 6, wherein the balls are adhered to the surface of the substrate with solder having a Brinell hardness number lower than 150

8. The ball grid array unit as claimed in 6, wherein the surface of the substrate includes an array of depressions in which the balls sit.

9. The ball grid array unit as claimed in claim 6, wherein the substrate is made of metal and the balls are made of metal.

10. A method of manufacturing a ball grid array unit suitable for calibrating an inspection system, comprising:
providing a substrate; and
mounting balls having a melting point greater than 400 degrees centigrade to a surface of the substrate.

11. A method as claimed in claim 10, wherein the step of mounting the balls on the surface of the substrate comprises soldering the balls to the surface of the substrate at a temperature of less than 400 degrees centigrade.

12. A method as claimed in claim 10, wherein the step of mounting the balls on the surface of the substrate comprises applying solder to the substrate, and positioning the balls in an array on the solder.

13. A method of manufacturing a ball grid array unit suitable for calibrating an inspection system, comprising:
providing a substrate; and
mounting balls having a Brinell hardness number lower than 150 to a surface of the substrate.

14. A method as claimed in claim 13, wherein the step of mounting the balls on the surface of the substrate comprises soldering the balls to the surface of the substrate using solder having a Brinell hardness number lower than 150.
